(19) United States
(12) Patent Application Publication
(10) Pub. No.: US 2026/0324404 A1
(43) Pub. Date: Oct. 15, 2026

(54) INTERCONNECTION LINE FOR SEMICONDUCTOR DEVICES AND SEMICONDUCTOR DEVICES INCLUDING SAME

(71) Applicant: Samsung Electronics Co., Ltd., Suwon-si (KR)

(72) Inventors: Jisoo Oh, Suwon-si (KR); Kiil Kim, Suwon-si (KR); Hyonwook Ra, Suwon-si (KR); Changbea Park, Suwon-si (KR); Sanghyun Lee, Suwon-si (KR); Kyungyub Jeon, Suwon-si (KR)

(21) Appl. No.: 19/413,457

(22) Filed: Dec. 9, 2025

(30) Foreign Application Priority Data
Apr. 15, 2025 (KR) 10-2025-0049066

(51) Int. Cl. H10W 20/41; H10W 20/42; H10W 20/43; H10D 30/00; H10D 30/01; H10D 62/13; H10D 64/23; H10D 84/01; H10W 20/00

(52) U.S. Cl. CPC H10W 20/435; H10W 20/42; H10W 20/43; H10D 30/019; H10D 30/502; H10D 62/151; H10D 64/256; H10D 84/0149; H10W 20/089

(57) ABSTRACT

A semiconductor device includes a substrate, an element layer on the substrate, a first interlayer insulating layer on the element layer, first interconnection lines extending in a first direction in the first interlayer insulating layer, a second interlayer insulating layer on the first interlayer insulating layer, and second interconnection structures in the second interlayer insulating layer, each of the second interconnection structures extending in a second direction, connected to a respective plurality of the first interconnection lines,, and respectively including a second interconnection line. Each of the second interconnection structures includes a lower region and an upper region, and has a bend portion between the lower region and the upper region, and in the second direction, a first separation distance between upper ends of the lower regions of the second interconnection structures is greater than a second separation distance between lower ends of the lower regions.

### CROSS-REFERENCE TO RELATED APPLICATION(S)

This application claims the benefit under 35 USC 119(a) of Korean Patent Application No. 10-2025-0049066 filed on Apr. 15, 2025, in the Korean Intellectual Property Office, the entire disclosure of which is incorporated herein by reference for all purposes.

### BACKGROUND

The present inventive concept relates to semiconductor devices.

As demand for high performance, high speed, and/or multifunctionality of semiconductor devices increases, the integration of semiconductor devices is increasing. In manufacturing semiconductor devices with fine patterns corresponding to the trend toward high integration of semiconductor devices, it is required to implement interconnection lines with fine widths or fine separation distances.

### SUMMARY

Example embodiments provide semiconductor devices having improved electrical characteristics.

According to example embodiments, a semiconductor device includes a substrate, an element layer including a semiconductor element on the substrate, a first interlayer insulating layer on the element layer, first interconnection lines in the first interlayer insulating layer, each of the first interconnection lines extending in a first direction parallel to an upper surface of the substrate, a second interlayer insulating layer

on the first interlayer insulating layer and the first interconnection lines, and second interconnection structures in the second interlayer insulating layer, each of the second interconnection structures extending in a second direction intersecting the first direction and spaced apart from each other in the second direction, each of the second interconnection structures connected to a respective plurality of the first interconnection lines, and each of the second interconnection structures respectively including a second interconnection line. Each of the second interconnection structures includes a lower region and an upper region on the lower region, and has a bend portion between the lower region and the upper region, and in the second direction, a first separation distance between an upper end of the lower region of a first one of the second interconnection structures and an upper end of the lower region of a second one of the second interconnection structures is greater than a second separation distance between a lower end of the lower region of the first one of the second interconnection structures and a lower end of the lower region of the second one of the second interconnection structures.

According to example embodiments, a semiconductor device includes first interconnection lines extending in a first direction, and second interconnection lines on the first interconnection lines and extending in a second direction intersecting the first direction, each of the second interconnection lines connected to a corresponding plurality of the first interconnection lines, and spaced apart from each other in the second direction. In each of the second interconnection lines, a first width of an upper end in the second direction is different from a second width of a lower end in the second direction, and each of the second interconnection lines includes an upper region including the upper end and having a side surface with a first slope, and a lower region having a side surface with a second slope that is different from the first slope.

According to example embodiments, a semiconductor device includes first interconnection structures, each respectively including a first interconnection line extending in a first direction, and second interconnection structures on the first interconnection structures and extending in a second direction, intersecting the first direction, each of the second interconnection structures spaced apart from each other in the second direction, each of the second interconnection structures connected to a respective plurality of the first interconnection structures, and each of the second interconnection structures respectively including a second interconnection line. Each of the second interconnection structures includes an upper region having a first side surface with a first slope and a lower region having a second side surface with a second slope that is different from the first slope, the first side surface of one of the second interconnection structures is shifted in the second direction from a side surface of one of the first interconnection structures that is adjacent to the second side surface of the one of the second interconnection structures, and the second side surface of the one of the second interconnection structures extends from the first side surface to the side surface or an upper surface of the one of the first interconnection structures that is adjacent to the second side surface.

### BRIEF DESCRIPTION OF DRAWINGS

The above and other aspects, features, and advantages of the present inventive concept will be more clearly understood from the following detailed description, taken in conjunction with the accompanying drawings, in which:

FIGS. 1A, 1B, and 1C, are plan views and cross-sectional views illustrating a semiconductor device according to example embodiments;

FIGS. 2A, 2B, and 2C, are plan views and cross-sectional views illustrating a semiconductor device according to example embodiments;

FIGS. 3A, 3B, and 3C, are plan views and cross-sectional views illustrating a semiconductor device according to example embodiments;

FIGS. 4A and 4B are cross-sectional views illustrating a semiconductor device according to example embodiments;

FIG. 5 is a cross-sectional view illustrating a semiconductor device according to example embodiments;

FIG. 6 is a cross-sectional view illustrating a semiconductor device according to example embodiments;

FIG. 7 is a cross-sectional view illustrating a semiconductor device according to example embodiments;

FIG. 8 is a cross-sectional view illustrating a semiconductor device according to example embodiments;

FIGS. 9A, 9B, 9C, and 9D, are drawings illustrating a process sequence of a method of manufacturing a semiconductor device according to example embodiments; and

FIGS. 10A and 10B are drawings illustrating a method of manufacturing a semiconductor device according to example embodiments.

### DETAILED DESCRIPTION

The present disclosure now will be described more fully hereinafter with reference to the accompanying drawings, in which various embodiments are shown. The invention may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail. The language of the claims should be referenced in determining the requirements of the invention.

Hereinafter, terms such as ‘on,’ ‘upper portion,’ ‘upper surface,’ ‘below,’ ‘lower portion,’ ‘lower surface,’ ‘side surface,’ and the like, unless otherwise described, may be understood to refer to the orientation as shown in the drawings and the relative description may be different for different orientations.

Terms such as “same,” “equal,” “planar,” “coplanar,” “parallel,” and “perpendicular,” as used herein encompass identicality or near identicality including variations that may occur resulting from conventional manufacturing processes. The term “substantially” may be used herein to emphasize this meaning, unless the context or other statements indicate otherwise.

It will be understood that when an element is referred to as being "connected" or "coupled" to or “on” another element, it can be directly connected or coupled to or on the other element or intervening elements may be present. In contrast, when an element is referred to as being "directly connected" or "directly coupled" to another element, or as “contacting” or “in contact with” another element (or using any form of the word “contact”), there are no intervening elements present at the point of contact.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be referenced elsewhere without an ordinal number or with a different ordinal number (e.g., “second” in the specification or another claim).

As used herein, a semiconductor device may refer to any of the various devices such as shown the figures, and may also refer, for example, to two transistors or a device such as a semiconductor chip (e.g., memory chip and/or logic chip formed on a die), a stack of semiconductor chips, a semiconductor package including one or more semiconductor chips stacked on a package substrate, or a package-on-package device including a plurality of packages. These devices may be formed using ball grid arrays, wire bonding, through substrate vias, or other electrical connection elements, and may include memory devices such as volatile or non-volatile memory devices.

Like reference characters refer to like elements throughout.

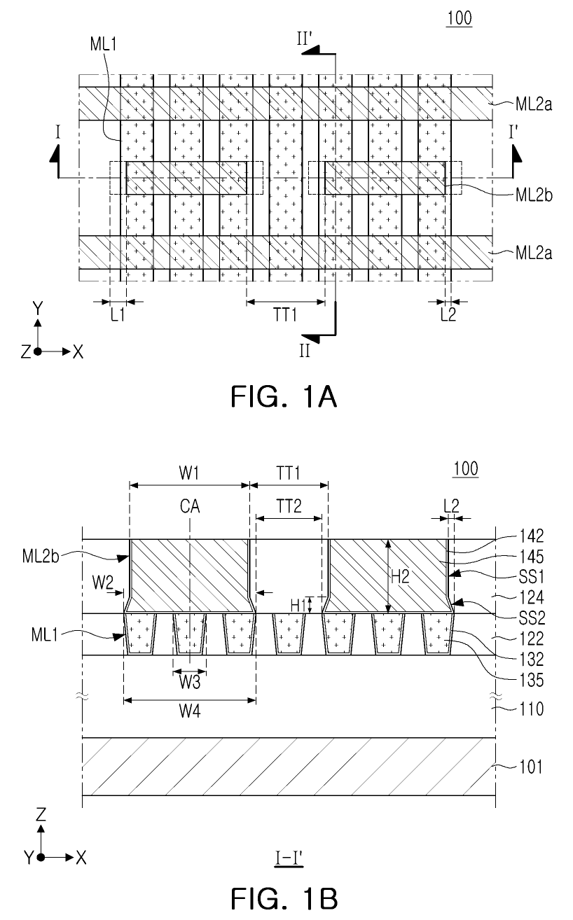

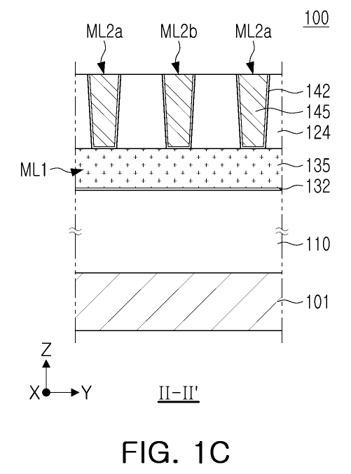

FIGS. 1A, 1B and 1C are plan views and cross-sectional views illustrating a semiconductor device according to example embodiments. FIG. 1B illustrates a cross-section of the semiconductor device of FIG. 1A taken along line I-I,’ and FIG. 1C illustrates a cross-section of the semiconductor device of FIG. 1A taken along line II-II’. For convenience of explanation, only some components of the semiconductor device are illustrated in FIG. 1A.

Referring to FIGS. 1A, 1B and 1C, a semiconductor device 100 may include a substrate 101, an element layer 110, a first interlayer insulating layer 122 on the element layer 110, first interconnection lines ML1 disposed within the first interlayer insulating layer 122, a second interlayer insulating layer 124 on the first interlayer insulating layer 122, and second interconnection lines ML2a and ML2b disposed within the second interlayer insulating layer 124.

The substrate 101 may have an upper surface extending in a first direction (e.g., the Y direction) and a second direction (e.g., the X direction). The substrate 101 may include a semiconductor material, for example, a group IV semiconductor, a group III-V compound semiconductor, or a group II-VI compound semiconductor. For example, the group IV semiconductor may include silicon, germanium, or silicon-germanium. The substrate 101 may be provided as a bulk wafer, an epitaxial layer, a Silicon On Insulator (SOI) layer, or a Semiconductor On Insulator (SeOI) layer. Active regions may be defined in the upper region of the substrate 101 by, for example, a device isolation layer. For example, the active regions may be portions of the upper region of the substrate 101 remaining between trenches formed in an upper surface of the substrate 101. The trenches may be filled by the device isolation layer.

The element layer 110 is disposed on the substrate 101 and may include semiconductor elements not illustrated in the figures. The element layer 110 may include at least one of, for example, a passive element, a transistor, a memory cell, an interconnection structure, or an insulating layer.

The first interlayer insulating layer 122 may be disposed on the element layer 110, and the second interlayer insulating layer 124 may be disposed on the first interlayer insulating layer 122. The first and second interlayer insulating layers 122 and 124 may be formed of an insulating material, and may include, for example, at least one of silicon oxide, silicon nitride, and/or silicon oxynitride. In some embodiments, at least one of the first and second interlayer insulating layers 122 and 124 may include a plurality of insulating layers.

The first interconnection lines ML1 may extend in a first direction (e.g., the Y direction) and may be spaced apart from each other in a second direction (e.g., the X direction). The first interconnection lines ML1 may be disposed in the first interlayer insulating layer 122. The upper surfaces of the first interconnection lines ML1 may be coplanar with the upper surface of the first interlayer insulating layer 122. The upper surfaces of the first interconnection lines ML1 may be exposed from the first interlayer insulating layer 122. The first interconnection lines ML1 may be physically and/or electrically connected to semiconductor elements, such as transistors, within the element

layer 110. The first interconnection lines ML1 may be electrically connected to second interconnection lines ML2a and ML2b on the first interconnection lines ML1. For example, the first interconnection lines ML1 may be 1-n-th interconnections from the element layer 110, and the second interconnection lines ML2a and ML2b may be the n+1-th interconnection. Each of the first interconnection lines ML1 may constitute a first interconnection structure, and each of the second interconnection lines ML2a and ML2b may constitute a second interconnection structure.

The first interconnection lines ML1 may each have a side surface that is inclined so that the width of each of the first interconnection lines ML1 decreases, from an upper surface of the first interconnection line ML1 facing away from the substrate to a lower surface facing the substrate 101. For example, the first interconnection lines ML1 may extend lengthwise in the Y direction and the widthwise in the X direction, which is perpendicular to the Y direction, may increase at locations farther from the substrate. However, in some embodiments, a first interconnection line ML1 may have a side surface that is inclined so that the width thereof increases, from the surface facing the substrate 101. The pitch of the first interconnection lines ML1, for example, the sum of the width and the separation distance between neighboring ones of the first interconnection lines ML1, may be in a range of, for example, about 20 nm to about 60 nm, and the height of the first interconnection lines ML1 may be in a range of, for example, about 20 nm to about 90 nm, but is not limited thereto.

The second interconnection lines ML2a and ML2b may form a second interconnection structure, and may extend lengthwise in a second direction, for example, in the X direction, on the first interlayer insulating layer 122 and the first interconnection lines ML1, and may be spaced apart from each other in the Y direction. Among the second interconnection lines ML2a and ML2b, the second main interconnection lines ML2a may extend relatively long in the X direction, and the second sub-interconnection lines ML2b may extend relatively short in the X direction (e.g., the second main interconnection lines ML2a may have a greater lengthwise direction relative to the lengthwise direction of the second sub-interconnection lines ML2b). Each of the second sub-interconnection lines ML2b may be spaced apart from an adjacent second sub-interconnection lines ML2b in the X direction. The second interconnection lines ML2a and ML2b may be physically and electrically connected to the first interconnection lines ML1 overlapping in the Z direction. However, the arrangements and forms of the first interconnection lines ML1 and the second interconnection lines ML2a and ML2b may be variously changed in the example embodiments.

The second interconnection lines ML2a and ML2b may be disposed in the second interlayer insulating layer 124. The upper surfaces of the second interconnection lines ML2a and ML2b may be coplanar with the upper surface of the second interlayer insulating layer 124. The upper surfaces of the second interconnection lines ML2a and ML2b may be exposed from the second interlayer insulating layer 124. Vias and other interconnection lines may be further disposed on the second interconnection lines ML2a and ML2b.

The pitch of the second interconnection lines ML2a and ML2b, for example, the sum of the width and separation distance of the second interconnection lines ML2a and ML2b, may be, for example, in a range of about 20 nm to about 60 nm, and the height of the second interconnection lines ML2a and ML2b may be, for example, in a range of about 50 nm to about 100 nm, but is not limited thereto.

The side surfaces of each of the second interconnection lines ML2a and ML2b in the Y direction may be inclined so that the width of the second interconnection lines ML2a and ML2b decreases toward the substrate 101, as illustrated in FIG. 1C (e.g., tapers from an upper end to a lower end). The side surfaces in the Y direction may have a substantially constant inclination from the upper end to the lower end, and accordingly, the width of the second interconnection lines ML2a and ML2b in the Y direction may be constantly changed. However, in some embodiments, the side surfaces in the Y direction may be vertical or may have an inclined shape so that the width of the second interconnection lines ML2a and ML2b increases while facing the substrate 101.

Each second sub-interconnection line ML2b may be in contact with and connected to a plurality of first interconnection lines ML1. The second sub-interconnection line ML2b may span the entire upper surfaces of the plurality of first interconnection lines ML1 connected thereto (e.g., may contact the entire upper surfaces in a direction perpendicular to the lengthwise direction of first interconnection lines). Each second sub-interconnection line ML2b may have a first width W1 in the X direction at the upper end and a second width W2 in the X direction larger than the first width W1 at the lower end. In the present embodiment, each second sub-interconnection line ML2b may have a cross-sectional shape that is symmetrical with respect to a central axis CA of the second sub-interconnection line ML2b (e.g., may be symmetric in the X axis with respect to a central Z axis of the second sub-interconnection line ML2b.). Each first interconnection line ML1 has a third width W3 in the X direction smaller than the first width W1, and a fourth width W4 in the X direction, which is the total width of the plurality of first interconnection lines ML1 connected to the second sub-interconnection line ML2b, may be substantially equal to the second width W2. However, in some embodiments, the fourth width W4 may be larger than the second width W2, but the difference between the fourth width W4 and the second width W2 may be smaller than the third width W3.

The second sub-interconnection line ML2b may not have a shape in which the width changes continuously from the first width W1 to the second width W2, but may have a region, such as a lower region, in which the width changes abruptly. The upper end of the lower region may have the first width W1 or a width reduced from the first width W1, and the lower end of the lower region may have a second width W2 larger than the width of the upper end of the lower region. In the lower region, the width of the second sub-interconnection line ML2b in the X direction may increase relatively rapidly (e.g., increase at a rate greater than a rate in the upper region). The side surfaces of the second sub-interconnection line ML2b in the X direction may have a bent or tilted shape in the lower region. For example, a slope of the side surfaces of the second sub-interconnection line ML2b in the X direction may change in the lower region.

The second sub-interconnection line ML2b may include an upper region having a first side surface SS1 with a first slope in the X direction and a lower region having a second side surface SS2 with a second slope that is gentler than the first slope (e.g., is closer to horizontal than the first slope). The first slope may be closer to the Z direction, which is a relatively vertical direction, or may be vertical, for example, at 90 degrees relative to an upper surface of the substrate 101. An angle between the first sloped side surface SS1 and the Z direction may be smaller than an angle between the second sloped side surface SS2 and the Z direction. The second sloped side surface SS2 may be a side surface connecting a lower end of the upper region and a first interconnection line ML adjacent thereto. For example, the upper region may have a vertical first side surface SS1 or an inclined first side surface SS1 inclined such that the width of the second sub-interconnection line ML2b decreases towards the substrate 101. The lower region may have a second side surface SS2 that is inclined such that a width of the second sub-interconnection line ML2b increases towards the substrate 101. On opposing sides of a second sub-interconnection line ML2b, the slopes of the second side surfaces SS2 may be symmetrical to each other, but are not limited thereto. For example, in some embodiments, depending on the length of the second sub-interconnection line ML2b and the relative arrangement with respect to the first interconnection lines ML1, the slopes of the second side surfaces SS2 may be asymmetrical to each other, and the absolute values of the slope angles may be different from each other.

Since the width of the second sub-interconnection line ML2b between the first side surface SS1 and the second side surface SS2 does not change by a continuous trend or the same function (e.g., there is a discontinuity in the slope between the first side surface SS1 and the second side surface SS2), a bend portion may be formed between the first side surface SS1 and the second side surface SS2 and between the upper region and the lower region. In the bend portion, the width of the second sub-interconnection line ML2b may be changed to a different trend or a different function, and may be bent or tilted to extend toward the adjacent first interconnection lines ML1.

The first height H1 of the lower region may be smaller than the second height H2, which is the entire height of the second sub-interconnection line ML2b. For example, the first height H1 may be half or less, about 30 % or less, for example, within a range of about 3 % to about 15 %, of the second height H2. For example, the first height H1 may be about 20 nm or less, for example, within a range of about 2 nm to about 10 nm and the second height may be about 130 nm or less, but is not limited thereto. In the upper region and the lower region, as described above, the side surfaces in the Y direction may have the same slope as each other.

The second sub-interconnection line ML2b may have a shape having a length in the X direction at an upper portion that is reduced by a first length L1 from both sides in the X direction compared to a reference shape or a shape of a comparative example, as illustrated in FIG. 1A. The reference shape may correspond to a shape in which the upper region of the second sub-interconnection line ML2b is extended outwardly of two ends of the first interconnection lines ML1 intersected thereto, in the X direction, as indicated by a dotted line in FIG. 1A. Accordingly, the upper region of the second sub-interconnection line ML2b may be located inwardly from two ends of the first interconnection lines ML1 by a second length L2.

The two ends in the X direction of the upper region and the first side surface SS1 may be located on the first interconnection lines ML1 and may overlap with the first interconnection lines ML1 in the Z direction. The two ends of the upper region and the first side surface SS1 may be positioned shifted inwardly in the X direction from the outer side surface of the adjacent first interconnection line ML1. The second side surface SS2 of the lower region may extend from the first side surface SS1 to the outer side surface or upper surface of the adjacent first interconnection line ML1.

Accordingly, compared to the case where the upper region of the second sub-interconnection lines ML2b is disposed in the reference shape, the first space TT1 corresponding to the tip-to-tip size between the second sub-interconnection lines ML2b may be greater than the distance between reference shapes. The first space TT1 may correspond to the width of the second interlayer insulating layer 124 between the second sub-interconnection lines ML2b (e.g., the distance in the X direction between adjacent second sub-interconnection lines ML2b at their uppermost surfaces). In the second sub-interconnection lines ML2b, the first space TT1 between the upper regions or between the upper ends may be larger than the second space TT2 between the lower ends. For example, the space between the lower regions may decrease from the first space TT1 to the second space TT2. By having the wider lower region, the second sub-interconnection line ML2b may have a form in which the length of the upper region is reduced, while still being able to contact the entire upper surfaces of the first interconnection lines ML1.

In the semiconductor device 100, by decreasing the length of the upper region of the second sub-interconnection lines ML2b, the first space TT1 increases, and thus the capacitance decreases, thereby improving the RC delay. In addition, the likelihood of a short with an adjacent first interconnection line ML1 that is not connected may be reduced or prevented. Additionally, contact resistance may be secured by including the lower region in which the second sub-interconnection lines ML2b have an expanded width.

Each of the first interconnection lines ML1 may include a first barrier layer 132 and a first conductive layer 135. The first barrier layer 132 may cover side surfaces and a bottom surface of the first conductive layer 135. Each of the second interconnection lines ML2a and ML2b may include a second barrier layer 142 and a second conductive layer 145. The second barrier layer 142 may cover side surfaces and a bottom surface of the second conductive layer 145. The first barrier layer 132 and the second barrier layer 142 may prevent diffusion of materials of the first conductive layer 135 and the second conductive layer 145, respectively.

The first barrier layer 132 and the second barrier layer 142 may include a conductive material, and may include, for example, at least one of titanium (Ti), a titanium nitride (TiN), tantalum (Ta), a tantalum nitride (TaN), ruthenium (Ru), cobalt (Co), manganese (Mn), a tungsten nitride (WN), nickel (Ni), or nickel boron (NiB). However, in some embodiments, the first barrier layer 132 and the second barrier layer 142 may be omitted. The first conductive layer 135 and the second conductive layer 145 may include a conductive material, and may include, for example, a metal material such as ruthenium (Ru), molybdenum (Mo), tungsten (W), copper (Cu), aluminum (Al), nickel (Ni), titanium (Ti), chromium (Cr), manganese (Mn), iron (Fe), or cobalt (Co). The first interconnection lines ML1 and the second interconnection lines ML2a and ML2b may include the same or different materials.

In the description of the example embodiments below, da description of features that would overlap with the description described above with reference to FIGS. 1A, 1B and 1C may be omitted with the understanding that the previous description is applicable.

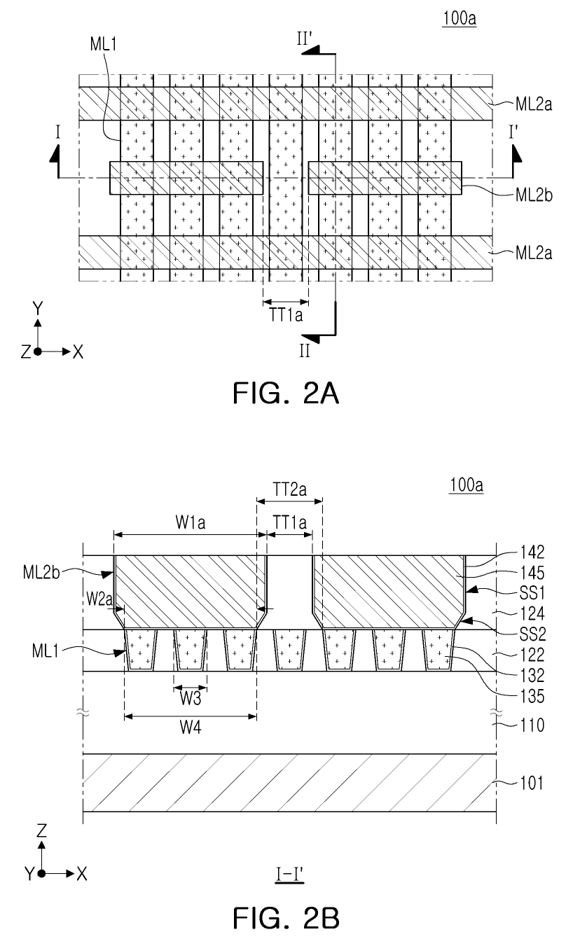

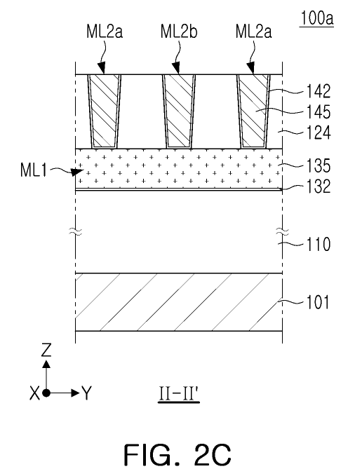

FIGS. 2A, 2B and 2C are plan views and cross-sectional views illustrating a semiconductor device according to example embodiments. FIG. 2B illustrates a cross-section of the semiconductor device of FIG. 2A taken along the cutting line I-I,’ and FIG. 2C illustrates a cross-section of the semiconductor device of FIG. 2A taken along the cutting line II-II’.

Referring to FIGS. 2A, 2B and 2C, in a semiconductor device 100a, the arrangement, position, and shape of the second sub-interconnection lines ML2b may be different from those in the example embodiments of FIGS. 1A, 1B and 1C.

The upper region of the second sub-interconnection line ML2b may have the above-described reference shape with reference to FIG. 1A. The two ends of the upper region of the second sub-interconnection line ML2b along the X direction may be located outside the two ends of the first interconnection lines ML1 connected thereto.

The second sub-interconnection line ML2b may have a first width W1a in the X direction at the upper end, and a second width W2a smaller than the first width W1a at the lower end. In the present embodiment, the second sub-interconnection line ML2b may have a shape that is symmetrical with respect to the central axis along the X direction. The fourth width W4, which is the total width of the plurality of first interconnection lines ML1 connected to the second sub-interconnection line ML2b, may be substantially equal to the second width W2a.

The width of the second sub-interconnection line ML2b in the X direction may decrease relatively rapidly in the lower region. For example, the upper region may have a first side surface SS1 that is vertical or inclined so that the width of the second sub- interconnection line ML2b decreases towards the substrate 101. The lower region may have a second side surface SS2 that is inclined so that the width of the second sub-interconnection line ML2b decreases towards the substrate 101. On both sides of one second sub-interconnection line ML2b, the inclinations of the second side surfaces SS2 may be symmetrical, but are not limited thereto. For example, in some embodiments, depending on the length of the second sub-interconnection line ML2b and the relative arrangement with respect to the first interconnection lines ML1, the inclinations of the second side surfaces SS2 may be asymmetrical to each other, and the absolute values of the inclination angles may be different from each other.

The two ends of the upper region in the X direction and the first side surface SS1 may be located on the outer region of the first interconnection lines ML1 and may not overlap with the first interconnection lines ML1 in the Z direction. The two ends of the upper region and the first side surface SS1 may be positioned shifted from the outer side surface of the first interconnection line ML1 to which they are connected in the X direction. The second side surface SS2 of the lower region may extend from the first side surface SS1 to the outer side surface or the upper surface of the first interconnection line ML1 to which they are connected.

In the second sub-interconnection lines ML2b, the first space TT1a between the upper regions or between the upper ends may be smaller than the second space TT2a between the lower ends. For example, the space between the lower regions may increase from the first space TT1a to the second space TT2a. Through the lower region, the second sub-interconnection line ML2b may contact the entire upper surfaces of the first interconnection lines ML1.

In the semiconductor device 100a, the lower region of the second sub-interconnection lines ML2b may have a bent shape, and may thus be stably connected to the first interconnection lines ML1, and a short with an adjacent first interconnection line ML1 that is not connected may be prevented.

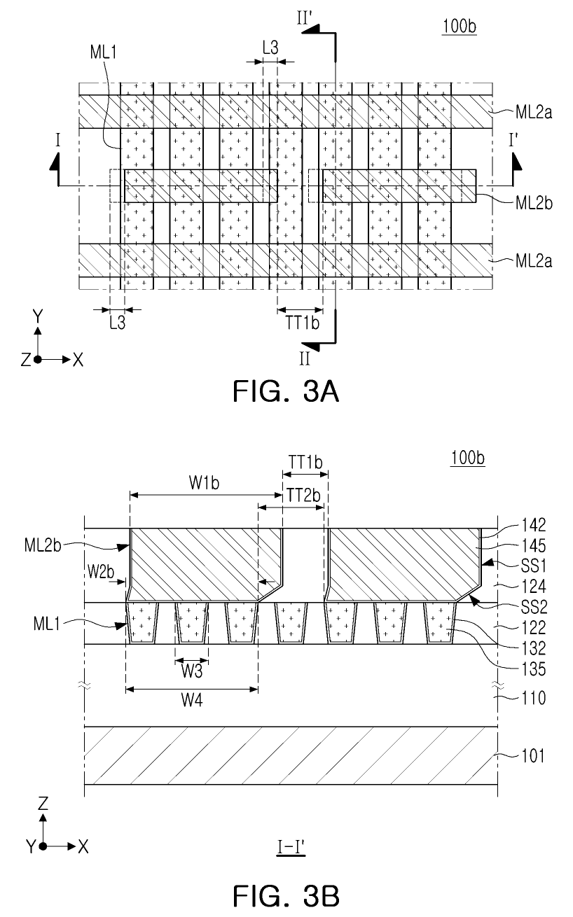

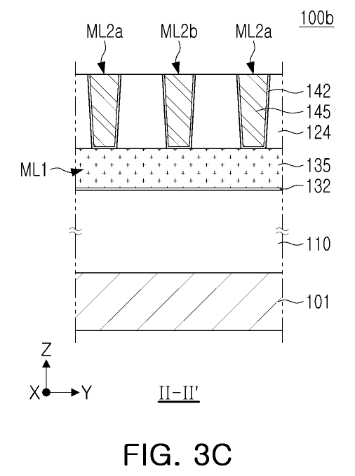

FIGS. 3A, 3B and 3C are plan views and cross-sectional views illustrating a semiconductor device according to example embodiments. FIG. 3B illustrates a cross-section of the semiconductor device of FIG. 3A taken along a cutting line I-I,’ and FIG. 3C illustrates a cross-section of the semiconductor device of FIG. 3A taken along a cutting line II-II’.

Referring to FIGS. 3A, 3B and 3C, in a semiconductor device 100b, the arrangement, position, and shape of the second sub-interconnection lines ML2b may be different from those in the example embodiments of FIGS. 1A, 1B and 1C.

The upper region of the second sub-interconnection line ML2b may be shifted by a third length L3 in the X direction from the above-described reference shape with reference to FIG. 1A. The second sub-interconnection line ML2b may be formed by intentionally changing the overlay or intentionally causing misalignment while using a photomask having the above-described reference shape. For example, if the tip-to-tip space between the second sub-interconnection line ML2b and a second sub-interconnection line ML2b to the left of FIG. 3A, which is not illustrated, is relatively small and there is a risk of defect occurrence, the second sub-interconnection line ML2b may be formed to shift in this way. However, in some embodiments, the second sub-interconnection line ML2b may be manufactured using a photomask having a pattern as illustrated in FIG. 3A.

The upper region of the second sub-interconnection line ML2b may not overlap with a part of the first interconnection lines ML1 connected, for example, the first interconnection line ML1 on the left side, in the Z direction. However, in example embodiments, the degree to which the second sub-interconnection line ML2b is shifted may be varied, and accordingly, the positions of the two ends of the upper region may also be varied.

The second sub-interconnection line ML2b may have a first width W1b at the upper end along the X direction, and a second width W2b smaller than the first width W1b at the lower end. In the present embodiment, the second sub-interconnection line ML2b may have an asymmetrical shape with respect to the central axis along the X direction. The fourth width W4, which is the total width of the plurality of first interconnection lines ML1 connected to the second sub-interconnection line ML2b, may be substantially the same as the second width W2b.

The slope of the second sub-interconnection line ML2b may be changed so that the width of the second sub-interconnection line ML2b along the X direction in the lower region is reduced. For example, the upper region may have a first side surface SS1 that is vertical, or inclined such that the width of the second sub-interconnection line ML2b decreases towards the substrate 101. The lower region may have a second side surface SS2 that is inclined such that the width of the second sub-interconnection line ML2b decreases towards the substrate and the second sub-interconnection line ML2b is bent in one direction. The inclinations of the second side surfaces SS2 on both sides of one second sub-interconnection line ML2b may be different from each other, but are not limited thereto. For example, in some embodiments, depending on the length of the second sub-interconnection line ML2b and the degree of shift described above, the inclinations of the second side surfaces SS2 may be the same and may be disposed in a parallel form to each other. The second side surface SS2 of the lower region may be extended from the first side surface SS1 to the outer side surface or upper surface of the first interconnection line ML1 connected thereto.

In the second sub-interconnection lines ML2b, the first space TT1b between the upper regions or between the upper ends may be smaller than the second space TT2b between the lower ends. However, the second sub-interconnection line ML2b on the left side of FIG. 3A may be relatively increased in tip-to-tip space with a second sub-interconnection lines ML2b that is disposed to the left and are not illustrated. Through the lower region, the second sub-interconnection line ML2b may be in contact with the entire upper surfaces of the first interconnection lines ML1.

In the semiconductor device 100b, by shifting the second sub-interconnection lines ML2b, a tip-to-tip space with the second sub-interconnection lines ML2b that are not illustrated may be increased, and thus, capacitance decreases, thereby improving the RC delay. In addition, since the lower region of the second sub-interconnection lines ML2b has a bent shape, stable connection with the first interconnection lines ML1 may be obtained, and a short with the first interconnection line ML1 that is not connected but adjacent thereto may be prevented.

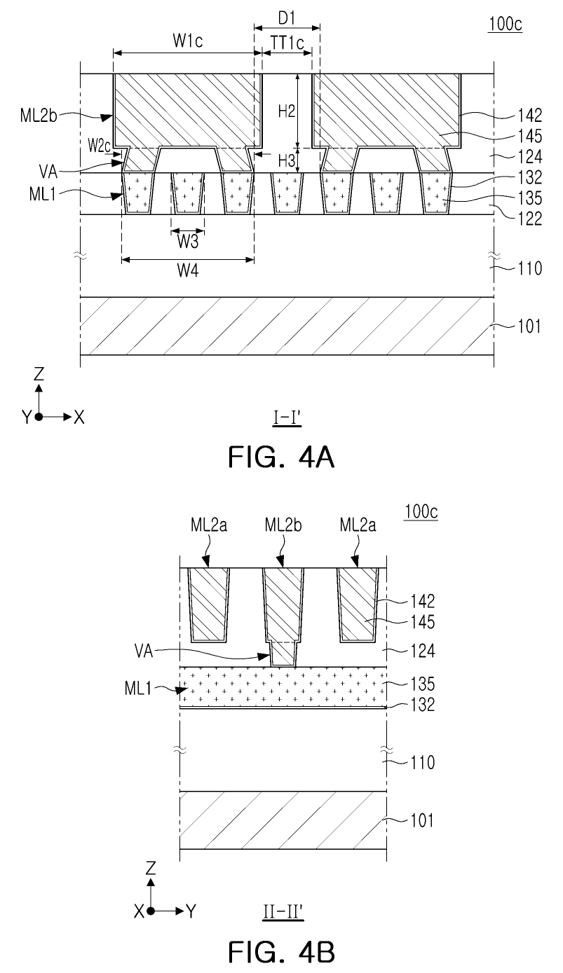

FIGS. 4A and 4B are cross-sectional views illustrating a semiconductor device according to example embodiments. FIGS. 4A and 4B illustrate regions corresponding to FIGS. 1B and 1C, respectively.

Referring to FIGS. 4A and 4B, in a semiconductor device 100c, unlike the example embodiments of FIGS. 1A, 1B and 1C, the second interconnection structure of the present embodiment may further include vias VA. The second interconnection lines ML2a and ML2b may form an upper region of the second interconnection structure, and the vias VA may form a lower region of the second interconnection structure.

The vias VA may have a cylindrical or truncated cone shape and may connect the first interconnection lines ML1 and the second interconnection lines ML2a and ML2b. The vias VA may be integral with the second interconnection lines ML2a and ML2b, but are not limited thereto. In this case, each of the vias VA may include a second barrier layer 142 and a second conductive layer 145 extending from the second interconnection lines ML2a and ML2b. The third height H3 of the vias VA may be smaller than the second height H2 of the second interconnection lines ML2a and ML2b.

The second interconnection structure may have a first width W1c at the upper end along the X direction, and a second width W2c that is a total width smaller than the first width W1c at the lower end. The second width W2c may correspond to the total width of the lower ends of the vias VA. However, the relative sizes of the first width W1c and the second width W2c may be changed such that one thereof is larger or the same depending on the relative arrangement of the vias VA and the second sub-interconnection line ML2b. The total width of the upper ends of the vias VA may have the first width W1c or a width reduced from the first width W1c, and the lower ends of the vias VA may have the second width W2c larger than the width of the upper ends. The fourth width W4, which is the total width of the plurality of first interconnection lines ML1 connected to the second interconnection structure, may be substantially the same as the second width W2c.

The vias VA may have side surfaces that are inclined toward the first interconnection lines ML1 to which they are connected. The vias VA may have side surfaces that are inclined so that the total width of the second interconnection structure increases from the second sub-interconnection line ML2b toward the first interconnection lines ML1. The width of the vias VA in the X direction may be maintained or decreased toward the substrate 101. In the present embodiment, the vias VA connected to one second sub-interconnection line ML2b may have shapes that are symmetrical to each other and may be inclined in opposite directions. For example, the vias VA may be inclined in the left and right directions, respectively, based on the Z direction. However, in some embodiments, vias VA connected to one second sub-interconnection line ML2b may not be symmetrical to each other, and the absolute values of the slope angles may be different from each other.

The first space TT1c between the second sub-interconnection lines ML2b may be smaller than the first separation distance D1 between the lower ends of the vias VA. However, the relative size of the first space TT1c and the first separation distance D1 may be changed so that one side is larger or the same depending on the relative arrangement of the vias VA and the second sub-interconnection line ML2b. The separation distance between the vias VA may decrease toward the substrate 101 to become the first separation distance D1.

The second sub-interconnection line ML2b may have a side surface with a first slope in the X direction, and the via VA may have a side surface of a second slope that is gentler than the first slope in the X direction. In addition, with respect to the inclined shapes of the vias VA, the first slope, and the second slope, the description of the lower region and the upper region of the second interconnection lines ML2a and ML2b described above with reference to FIGS. 1A, 1B and 1C may be equally applied.

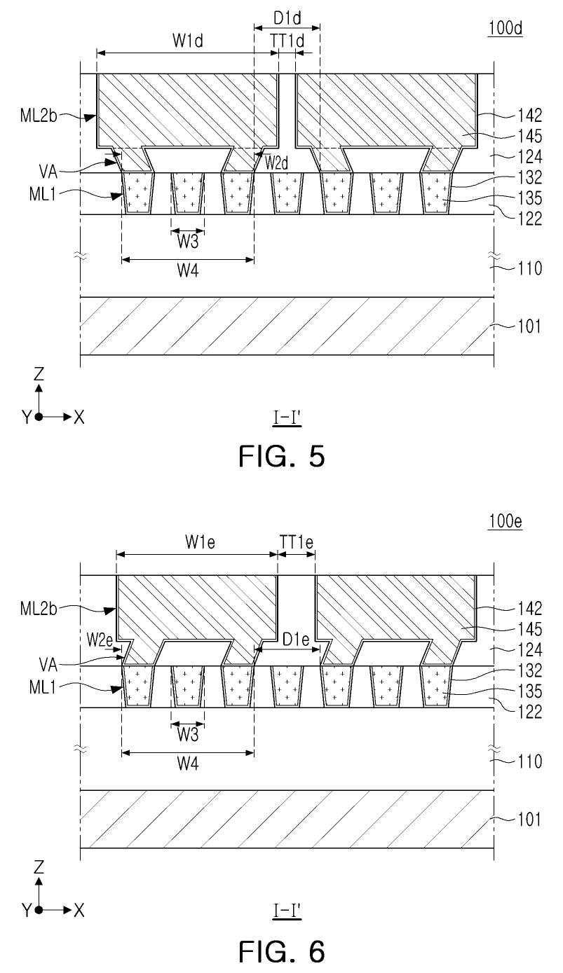

FIG. 5 is a cross-sectional view illustrating a semiconductor device according to example embodiments. FIG. 5 illustrates an area corresponding to FIG. 2B.

Referring to FIG. 5, in a semiconductor device 100d, the second interconnection structures may include second interconnection lines ML2a and ML2b and vias VA, unlike the example embodiments of FIGS. 2A, 2B and 2C. In addition, the inclination shape of the vias VA may be different from that of the example embodiment of FIG. 4A.

The second interconnection structure may have a first width W1d at an upper end along the X direction, and a second width W2d that is a total width smaller than the first width W1d at a lower end. A fourth width W4 that is a total width of a plurality of first interconnection lines ML1 connected to the second interconnection structure may be substantially equal to the second width W2d.

The vias VA may have side surfaces that are inclined toward the first interconnection lines ML1 to which they are connected. The vias VA may have side surfaces that are inclined so that the overall width of the second interconnection structure decreases as they move from the second sub-interconnection line ML2b toward the first interconnection lines ML1. The width of the vias VA in the X direction may be maintained or decreased as they move toward the substrate 101. In the present embodiment, the vias VA connected to one second sub-interconnection line ML2b may have a shape that is symmetrical to each other and may be inclined in opposite directions to each other. However, in some embodiments, the vias VA connected to one second sub-interconnection line ML2b may not be symmetrical to each other and the absolute values of the inclination angles may be different from each other.

The first space TT1d between the second sub-interconnection lines ML2b may be smaller than the first separation distance D1d between the lower ends of the vias VA. The separation distance between the vias VA may increase toward the substrate 101 to become the first separation distance D1d.

The second sub-interconnection line ML2b may have a side surface with a first slope in the X direction, and the via VA may have a side surface of a second slope that is gentler than the first slope in the X direction. In addition, the description of the lower region and the upper region of the second interconnection lines ML2a and ML2b described above with reference to FIGS. 2A, 2B and 2C may be equally applied to the inclined shape of the vias VA, the first slope, the second slope, and the like.

FIG. 6 is a cross-sectional view illustrating a semiconductor device according to example embodiments. FIG. 6 illustrates an area corresponding to FIG. 3B.

Referring to FIG. 6, in a semiconductor device 100e, the second interconnection structures may include second interconnection lines ML2a and ML2b and vias VA, unlike the example embodiments of FIGS. 3A, 3B and 3C. In addition, the inclined shapes of the vias VA may be different from those of the example embodiments of FIGS. 4A and 5.

The second interconnection structure may have a first width W1e at an upper end along the X direction, and a second width W2e that is a total width smaller than the first width W1e at a lower end. A fourth width W4 that is a total width of a plurality of first interconnection lines ML1 connected to the second interconnection structure may be substantially the same as the second width W2e.

The vias VA may have side surfaces that are inclined toward the first interconnection lines ML1 connected thereto. The vias VA may have inclined side surfaces so that the entire width of the second interconnection structure is maintained while facing the first interconnection lines ML1 from the second sub-interconnection line ML2b. The width of the vias VA in the X direction may be maintained or decreased while facing the substrate 101. In the present embodiment, the vias VA connected to one second sub-interconnection line ML2b may have the same shape. However, in some embodiments, the vias VA connected to one second sub-interconnection line ML2b may have different shapes, for example, may have different inclinations while having the same direction.

The first space TT1e between the second sub-interconnection lines ML2b may be smaller than, but is not limited to, the first separation distance D1e between the lower ends of the vias VA. The second sub-interconnection line ML2b may have a side surface with a first slope in the X direction, and the via VA may have a side surface of a second slope that is gentler than the first slope in the X direction. In addition, with respect to the inclined shape of the vias VA, the first slope, the second slope, and the like, the description for the lower region and the upper region of the second interconnection lines ML2aand ML2b described above with reference to FIGS. 3A, 3B and 3C may be equally applied.

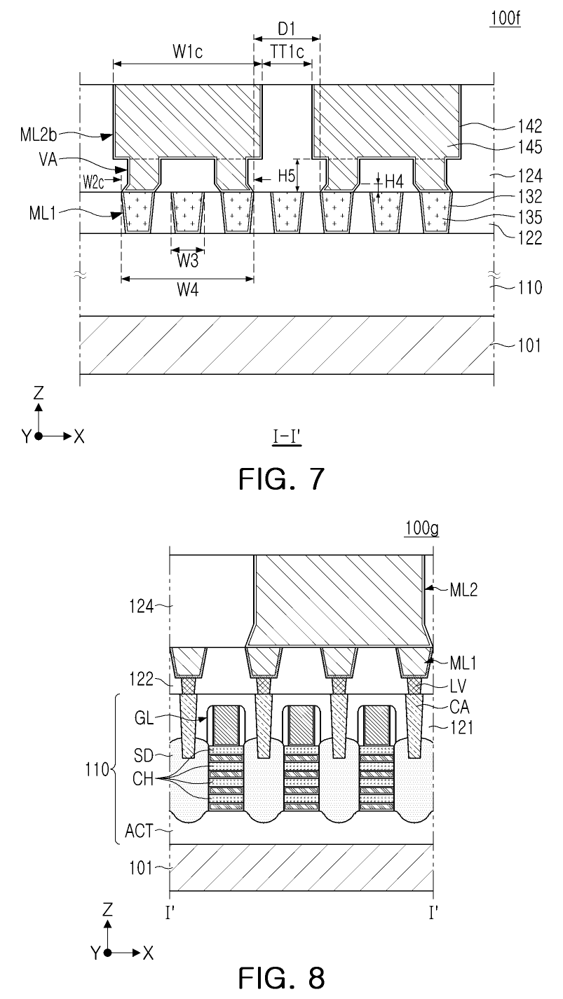

FIG. 7 is a cross-sectional view illustrating a semiconductor device according to example embodiments. FIG. 7 illustrates an area corresponding to FIG. 4A.

Referring to FIG. 7, in a semiconductor device 100f, unlike the example embodiment of FIG. 4A, the slopes of an upper region and a lower region of the vias VA may be different from each other.

In the via VA, the fourth height H4 of the lower region may be smaller than the fifth height H5, which is the overall height of the via VA. The slope of the lower region is gentler than the slope of the upper region. The lower region of the via VA may have side surfaces that are inclined so that the overall width of the second interconnection structure increases from the upper region toward the first interconnection lines ML1.

In this way, in the example embodiments, the slope may be changed and bent within the via VA, not the entire via VA. Similarly, the example embodiments of FIGS. 5 and 6 may also be applied with a structure in which the slope is changed and bent within the via VA.

FIG. 8 is a cross-sectional view illustrating a semiconductor device according to example embodiments.

Referring to FIG. 8, in a semiconductor device 100g, the element layer 110 may include an active region ACT, a plurality of channel layers CH disposed vertically spaced from each other on the active region ACT, gate lines GL extending across the active region ACT and respectively including a gate electrode, source/drain regions SD contacting the plurality of channel layers CH, contact plugs CA connected to the source/drain regions SD, and a lower interlayer insulating layer 121.

In the element layer 110, the active region ACT may have a fin structure, and the gate electrode may be disposed to surround the plurality of channel layers CH. Accordingly, the element layer 110 may include transistors of a Multi Bridge Channel FET (MBCFET^{TM}) structure, which is a gate-all-around type field effect transistor.

The active region ACT may be defined by a device isolation layer and may be disposed to extend in a first direction, for example, in the X direction. The active region ACT may be described as a configuration included in the upper region of the substrate 101. The active region ACT may be formed as a part of the substrate 101 or may include an epitaxial layer grown from the substrate 101. In example embodiments, the active region ACT may or may not include a well region including impurities.

The gate lines GL may be disposed to extend in a second direction, for example, in the Y direction, by crossing the active region ACT and the plurality of channel layers CH on the active region ACT and the plurality of channel layers CH. The functional channel regions of the transistors may be formed in the active region ACT and/or the plurality of channel layers CH intersecting the gate electrodes of the gate lines GL. Each of the gate lines GL may include a gate electrode, gate dielectric layers between the gate electrode and the plurality of channel layers CH, and gate spacer layers on the side surfaces of the gate electrode. The gate electrode may include a conductive material, and the gate dielectric layers and the spacer layers may include a dielectric material.

The plurality of channel layers CH may be disposed on the active region ACT in the regions where the active region ACT and the gate lines GL intersect. The plurality of channel layers CH may include two or more, for example, four channel layers. The plurality of channel layers CH may be connected to the source/drain regions SD. The plurality of channel layers CH may be made of a semiconductor material.

The source/drain regions SD may be disposed in recessed regions that partially recess the upper portion of the active region ACT on both sides of the gate lines GL. The source/drain regions SD may be disposed to cover side surfaces of the plurality of respective channel layers CH along the X direction. The source/drain regions SD may include a semiconductor material and may further include dopants. The source/drain regions SD may be formed of an epitaxial layer.

The contact plugs CA may be connected to the source/drain regions SD by penetrating the lower interlayer insulating layer 121 on the source/drain regions SD, and may apply an electrical signal to the source/drain regions SD. The contact plugs CA may be disposed in a form in which the source/drain regions SD are partially recessed, but are not limited thereto. The contact plugs CA may include a conductive material. In some embodiments, each of the contact plugs CA may include a metal silicide layer positioned at a lower end including a lower surface, and may further include a barrier layer. An interconnection structure such as a contact plug may be further disposed on the gate lines GL.

The lower vias LV may be disposed within the first interlayer insulating layer 122 on the contact plugs CA, and may connect the contact plugs CA and the first interconnection lines ML1. The lower vias LV may include a conductive material. The descriptions described above with reference to FIGS. 1A, 1B and 1C may be equally applied to the first interconnection lines ML1 and the second interconnection lines ML2. In example embodiments, the second interconnection structures including the second interconnection lines ML2 may have the structures of FIGS. 2A-7.

In FIG. 8, as an example of an element layer 110, the element layer 110 includes transistors of the MBCFET^{TM} structure, but the semiconductor elements disposed in the element layer 110 are not limited thereto.

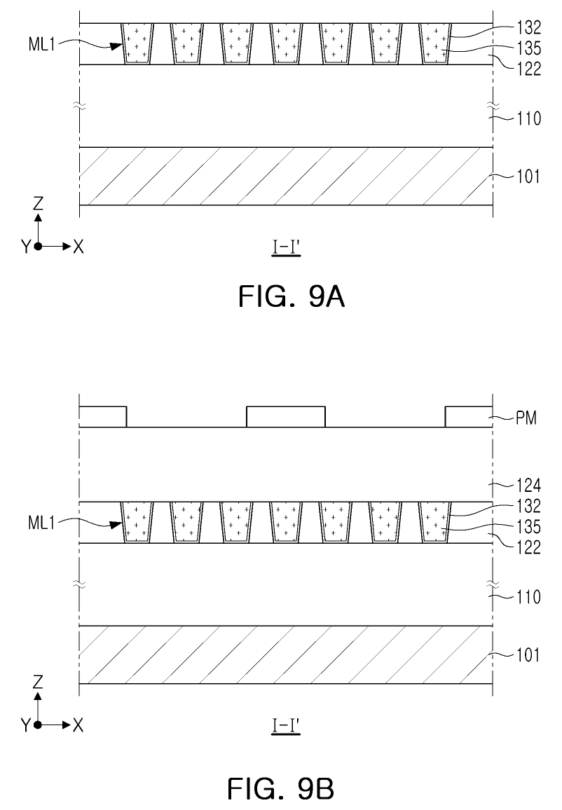

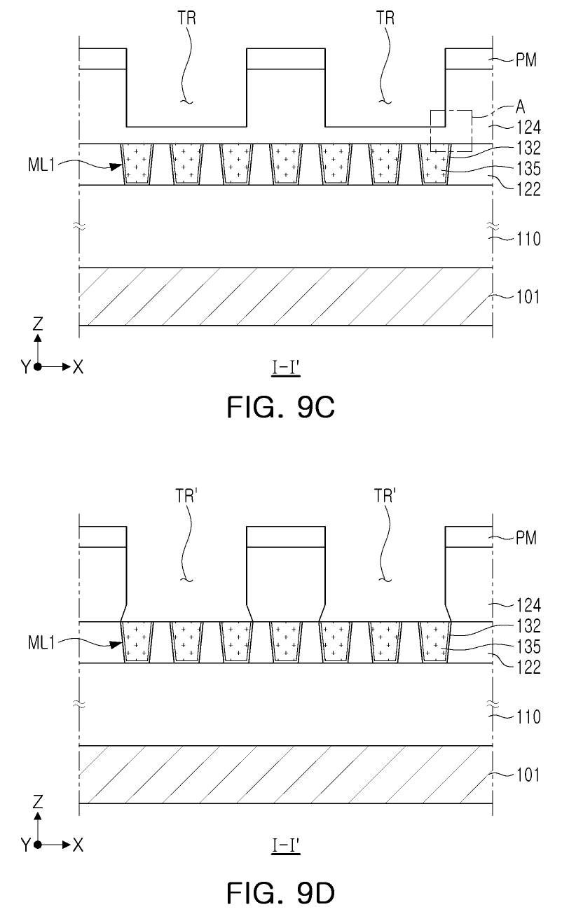

FIGS. 9A, 9B, 9C and 9D are drawings illustrating a method of manufacturing a semiconductor device according to example embodiments according to a process sequence. FIGS. 9A, 9B, 9C and 9D illustrate an example of a manufacturing method for manufacturing the semiconductor device of FIGS. 1A, 1B and 1C.

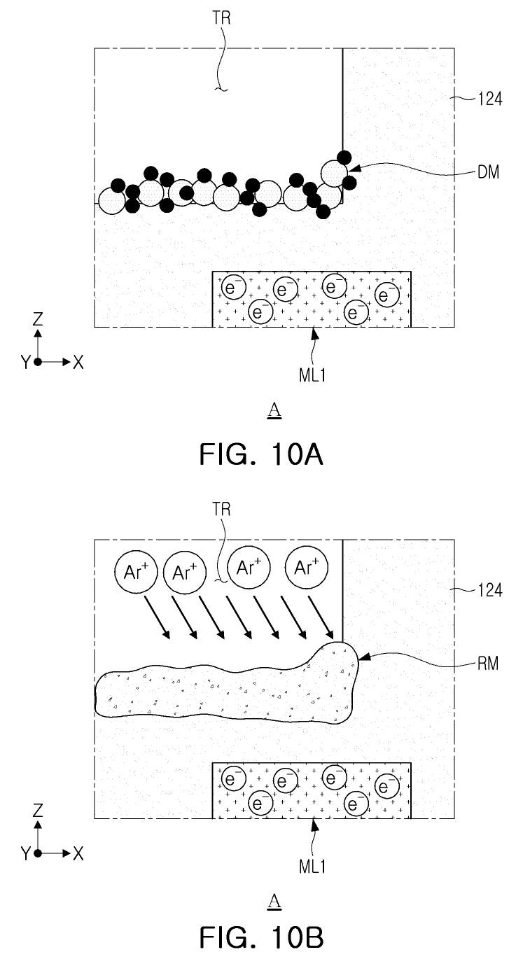

FIGS. 10A and 10B are drawings illustrating a method of manufacturing a semiconductor device according to example embodiments. FIGS. 10A and 10B illustrate an enlarged view of an area corresponding to area ‘A’ of FIG. 9C.

Referring to FIG. 9A, first interconnection lines ML1 embedded in a first interlayer insulating layer 122 and having upper surfaces exposed may be formed.

First, a substrate structure may be prepared. The substrate structure may include a substrate 101 and an element layer 110 on the substrate 101.

The first interconnection lines ML1 may be formed, for example, by forming a first interlayer insulating layer 122, removing a portion of the first interlayer insulating layer 122 to form trenches, depositing a conductive material in the trenches, and then performing a planarization process such as a chemical mechanical polishing (CMP) process. The above deposition process may be performed by an Atomic Layer Deposition (ALD) or Chemical Vapor Deposition (CVD) process. The first interconnection lines ML1 may be formed so that the upper surfaces are exposed, and the levels of the upper surfaces may be substantially the same.

Referring to FIG. 9B, a second interlayer insulating layer 124 may be formed on the first interlayer insulating layer 122 and the first interconnection lines ML1, and a mask layer PM may be formed.

The second interlayer insulating layer 124 may be formed to cover the upper surface of the first interlayer insulating layer 122 and the upper surfaces of the first interconnection lines ML1. The mask layer PM may be formed by being patterned by a photolithography process to expose areas corresponding to the second interconnection lines ML2a and ML2b of FIGS. 1A, 1B and 1C. The mask layer PM may be, for example, a photoresist layer. In some embodiments, the mask layer PM may further include a hard mask layer including at least one of silicon oxide, silicon nitride, and silicon carbide.

Referring to FIG. 9C, the second interlayer insulating layer 124 may be partially removed using the mask layer PM.

The second interlayer insulating layer 124 may be partially removed, for example, by atomic layer etching (ALE). Accordingly, the second interlayer insulating layer 124 may be etched and removed layer by layer from the upper surface. The process of forming the openings TR by removing the second interlayer insulating layer 124 by ALE will be described in more detail with reference to FIGS. 10A and 10B.

Referring to FIG. 10A, a reactive material DM may be deposited to react with the second interlayer insulating layer 124. The reactive material DM may be changed depending on the material of the second interlayer insulating layer 124, and may include, for example, a CₓF_{y} material, which is a perfluorocarbon. The reactive material DM may include, for example, at least one of CF₄, C₄F₆, and C₄F₈, and may be supplied in a gaseous state. The reactive material DM may react with the surface of the second interlayer insulating layer 124 to form a surface reactive layer RM (see FIG. 10B). The surface reactive layer RM may include, for example, SiF, SiC, or the like.

Referring to FIG. 10B, the surface reactive layer RM may be removed using an activated cation.

The surface reactive layer RM may be removed by sputtering with an activated cation, for example, an argon cation (Ar⁺) formed by activating an inert gas, argon (Ar). The activation may be, for example, by plasma generation. In some embodiments, in addition to Ar⁺, a krypton cation (Kr⁺) or a xenon cation (Xe⁺) may be used.

The activated cation may have a directionality toward free electrons (e-) in the first interconnection line ML1 below. Therefore, the second interlayer insulating layer 124 may be etched primarily in the direction toward the first interconnection line ML1 by such a charge effect. In this step, the degree to which the opening TR is tilted toward the first interconnection line ML1 may be controlled by controlling at least one of the power for activating the inert gas, for example, the plasma power or the flow rate of the inert gas.

The steps described above with reference to FIGS. 10A and 10B may be performed repeatedly in multiple cycles.

Referring to FIG. 9D, the second interlayer insulating layer 124 may be removed to form the final openings TR’.

The openings TR’ may include a region that is bent at the lower portion and has a wider width due to the charge effect described above. The openings TR’ may be formed to be self-aligned to the first interconnection lines ML1, and the upper surfaces of the first interconnection lines ML1 may be exposed through the bottom surface of the openings TR’.

Next, referring to FIG. 1B together, a conductive material may be deposited on the openings TR’ to form the second interconnection lines ML2a and ML2b. The second interconnection lines ML2a and ML2b may be self-aligned and connected to the first interconnection lines ML1. As a result, the semiconductor device 100 of FIGS. 1A, 1B, and 1C, may be manufactured.

According to example embodiments, a method of manufacturing a semiconductor device includes forming first interconnection lines buried in a first interlayer insulating layer and having upper surfaces exposed, forming a second interlayer insulating layer on the first interlayer insulating layer and the first interconnection lines, etching the second interlayer insulating layer from an upper surface by atomic layer etching (ALE) to form openings exposing the first interconnection lines, and depositing a conductive material in the openings to form second interconnection structures. The forming of the openings includes forming a mask layer on a portion of the second interlayer insulating layer, depositing a reactive material on the second interlayer insulating layer exposed from the mask layer to react with the second interlayer insulating layer, and activating an inert gas to generate cations to remove a surface reaction layer formed by a reaction of the reactive material and the second interlayer insulating layer. In the removing the surface reaction layer, the openings may be formed to have a tilting region toward the first interconnection lines.

In some embodiments, the tilting region may be adjusted by controlling at least one of the power for activating the inert gas or a flow rate of the inert gas.

In some embodiments, the cations may include at least one of argon cation (Ar⁺), krypton cation (Kr⁺), or xenon cation (Xe⁺).

In some embodiments, each of the second interconnection structures may include an upper region including an upper end and having a side surface with a first slope, and a lower region corresponding to the tilting region and having a side surface with a second slope, different from the first slope.

In the example embodiments, the second slope may be gentler than the first slope.

In the example embodiments, each of the second interconnection structures may have a bend portion between the upper region and the lower region.

In some embodiments, the tilting region may be formed on both sides along an extension direction of the openings.

In the example embodiments, the tilting region may not be formed on both sides along a direction perpendicular to the extension direction of the openings.

In some embodiments, each of the second interconnection structures may include a second interconnection line, and the second interconnection line may include an area corresponding to the tilting region.

In some embodiments, each of the second interconnection structures may include a via, and the via may include an area corresponding to the tilting region.

As set forth above, according to an example embodiment, a semiconductor device with improved electrical characteristics may be provided by tilting a lower region of an interconnection structure using a charge effect during atomic layer etching (ALE).

While example embodiments have been illustrated and described above, it will be apparent to those skilled in the art that modifications and variations could be made without departing from the scope of the present inventive concept as defined by the appended claims.

What is claimed is:

1. A semiconductor device comprising:
a substrate;
an element layer including a semiconductor element on the substrate;
a first interlayer insulating layer on the element layer;
first interconnection lines in the first interlayer insulating layer, each of the first interconnection lines extending in a first direction parallel to an upper surface of the substrate;
a second interlayer insulating layer on the first interlayer insulating layer and the first interconnection lines; and
second interconnection structures in the second interlayer insulating layer, each of the second interconnection structures extending in a second direction intersecting the first direction and spaced apart from each other in the second direction, each of the second interconnection structures connected to a respective plurality of the first interconnection lines, and each of the second interconnection structures respectively including a second interconnection line,
wherein each of the second interconnection structures includes a lower region and an upper region on the lower region, and has a bend portion between the lower region and the upper region, and
wherein, in the second direction, a first separation distance between an upper end of the lower region of a first one of the second interconnection structures and an upper end of the lower region of a second one of the second interconnection structures is greater than a second separation distance between a lower end of the lower region of the first one of the second interconnection structures and a lower end of the lower region of the second one of the second interconnection structures.

2. The semiconductor device of claim 1, wherein each of the second interconnection structures contacts upper surfaces of the respective plurality of the first interconnection lines, and spans across the upper surfaces of the respective plurality of the first interconnection lines in the second direction.

3. The semiconductor device of claim 2, wherein for each of the second interconnection structures, a width of a lower end in the second direction is the same as a total width of the respective plurality of the first interconnection lines.

4. The semiconductor device of claim 1, wherein in each of the second interconnection structures, a respective second interconnection line has the bend portion.

5. The semiconductor device of claim 4, wherein in each of the second interconnection structures, a respective second interconnection line is bent in the second direction toward a respective one of the first interconnection lines connected thereto.

6. The semiconductor device of claim 4, wherein in each of the second interconnection structures, the respective second interconnection line has a shape that is symmetrical with respect to a central axis in the second direction.

7. The semiconductor device of claim 1, wherein in each of the second interconnection structures, a respective bend portion is on a side surface along the second direction of a respective one of the second interconnection structures.

8. The semiconductor device of claim 7, wherein each of the second interconnection structures does not have a bend portion on side surfaces along the first direction of a respective one of the second interconnection structures.

9. The semiconductor device of claim 1, wherein in each of the second interconnection structures, a height of the lower region is smaller than a height of the upper region.

10. The semiconductor device of claim 1, wherein in each of the second interconnection structures a height of the lower region is in a range of 2 nm to 10 nm.

11. The semiconductor device of claim 1, wherein each of the second interconnection structures further includes a via connecting the second interconnection line of a respective one of the second interconnection structures and a corresponding one of the first interconnection lines.

12. The semiconductor device of claim 11, wherein for each of the second interconnection structures, the respective via has a side surface inclined in the second direction toward a corresponding one of the first interconnection lines connected thereto.

13. The semiconductor device of claim 11, wherein each of the second interconnection structures includes a plurality of vias inclined in opposite directions.

14. A semiconductor device comprising:
first interconnection lines extending in a first direction; and
second interconnection lines on the first interconnection lines and extending in a second direction intersecting the first direction, each of the second interconnection lines connected to a corresponding plurality of the first interconnection lines and spaced apart from each other in the second direction,
wherein in each of the second interconnection lines, a first width of an upper end in the second direction is different from a second width of a lower end in the second direction, and
wherein each of the second interconnection lines includes an upper region including the upper end and having a side surface with a first slope, and a lower region having a side surface with a second slope that is different from the first slope.

15. The semiconductor device of claim 14, wherein an angle between the first slope and a third direction perpendicular to upper surfaces of the second interconnection lines is smaller than an angle between the second slope and the third direction.

16. The semiconductor device of claim 14, wherein the side surface of the upper region and the side surface of the lower region are side surfaces in the second direction.

17. The semiconductor device of claim 16, wherein in each of the second interconnection lines, a side surface of the upper region in the first direction and a side surface of the lower region in the first direction have the same slope.

18. The semiconductor device of claim 14, wherein in each of the second interconnection lines, the second slope is a slope connecting a lower end of the upper region of a respective one of the second interconnection lines and a respective plurality of first interconnection lines adjacent to the lower region of the respective one of the second interconnection lines.

19. A semiconductor device comprising:
first interconnection structures, each respectively including a first interconnection line extending in a first direction; and
second interconnection structures on the first interconnection structures and extending in a second direction intersecting the first direction, each of the second interconnection structures spaced apart from each other in the second direction, each of the second interconnection structures connected to a respective plurality of the first interconnection structures, and each of the second interconnection structures respectively including a second interconnection line,
wherein each of the second interconnection structures includes an upper region having a first side surface with a first slope and a lower region having a second side surface with a second slope that is different from the first slope,
wherein the first side surface of one of the second interconnection structures is shifted in the second direction from a side surface of one of the first interconnection structures that is adjacent to the second side surface of the one of the second interconnection structures, and
wherein the second side surface of the one of the second interconnection structures extends from the first side surface to the side surface or an upper surface of the one of the first interconnection structures that is adjacent to the second side surface.

20. The semiconductor device of claim 19, wherein the second slope is gentler than the first slope.
